(19) United States
(12) Patent Application Publication
(10) Pub. No.: US 2020/0117256 A1
(43) Pub. Date: Apr. 16, 2020

(54) COMBINED TYPE AC/DC POWER SUPPLY

(71) Applicant: PHIHONG TECHNOLOGY CO., LTD., Taoyuan City (TW)

(72) Inventors: Banson Yang, Taoyuan City (TW); Paul Liu, Taoyuan City (TW); Krone Chiang, Taoyuan City (TW); Mason Lee, Taoyuan City (TW); Scott Lin, Taoyuan City (TW); Jimmy Chen, Taoyuan City (TW)

(21) Appl. No.: 16/218,539

(22) Filed: Dec. 13, 2018

(30) Foreign Application Priority Data
Oct. 16, 2018 (TW) 107136401

(51) Int. Cl. G06F 1/26; H01F 27/30; H05K 1/02; H02M 1/08; H02M 7/00

(52) U.S. Cl. CPC G06F 1/263; H01F 27/30; H02M 7/003; H02M 1/08; H05K 1/0213

(57) ABSTRACT

A combined type AC/DC power supply includes a first circuit module containing a first printed circuit board (PCB), an AC power input circuit being set on the first PCB, a first structural portion of a detachable bobbin being set on the first PCB, a primary side winding being wound around the first structural portion of the detachable bobbin and electrically connected to the first PCB and the AC power input circuit, a second circuit module containing a second PCB, a DC power output circuit being set on the second PCB, a second structural portion of the detachable bobbin being set on the second PCB with a secondary side winding being wound around and electrically connected to the second PCB and the DC power output circuit, wherein the AC and the DC power output circuit are structurally connected through the first and the second structural portion of the detachable bobbin.

### TECHNICAL FIELD

The present invention generally relates to power supplies, and more particularly to a combined type AC/DC power supply.

### BACKGROUND

Many of today's electronic systems require power supplies/adapters that can provide power to portable electronic devices, such as laptop computer, tablet, cellular phone, smart phone, and media player, etc. The power supplies/adapters acquire electrical power from external power source that can provide AC voltage and convert the AC voltage into DC voltage for operating equipments of the electronic devices or supporting their internal battery recharging. The power supplies/adapters may be limited to a single type of external power source and be operated for a specific device, which can operate with other power adapters with interchangeable plugs or other input devices for integrating together with multiple power sources, or provide backup outputs.

Recently, a general trend in designing portable electronic devices has been toward to small size, light weight and portability. If an external power supply unit is not provided to power the portable electronic device, the internal battery is typically used as the primary power source. When the power supplied from the battery is inefficient, the user can simply plug the AC/DC power supply/adapter plug into an AC wall outlet that is common in most houses or offices to receive the AC voltage. The AC voltage is then converted into a DC power source for use in the portable electronic device and/or to charge the internal battery.

While these power adapters provide stable DC voltage and charging capability, there are still some disadvantages. For example, users need to carry individual power supplies/adapters to provide power to each portable device. If user carries two or snore portable electronic devices selected from a computer, tablet, mobile phone, and media player a time, the user is forced to carry multiple power supplies/adapters. In such case, volume and weight of carried luggage will increase.

The conventional AC/DC power supply is designed to have a fixed output DC voltage. If a different DC voltage output is required, it needs to be designed separately. Therefore, there is a need for an AC power input module and a DC voltage output module. If a different DC voltage output is required, only the DC voltage output module needs to be replaced. The power is supplied by the user connecting the electronic device that needs to be charged.

In order to solve the above issue, the present invention proposes to divide the transformer of the conventional AC/DC power supply/adapter into two separate parts, i.e. the primary side and the secondary side of the transformer. The primary side transformer is placed in an AC power input module and the secondary side transformer is placed in a DC voltage output module. The two modules are combined to obtain a desired output voltage. The present invention can realize the modularization of different output voltages by making the input and output into two different modules, using the same input module, and replacing the output modules according to different output voltage requirements.

### SUMMARY

In this invention, a combined type AC/DC power supply is proposed.

A combined type AC/DC power supply includes a first circuit module containing a first printed circuit board (PCB), an AC power input circuit being set on the first PCB, a first structural portion of a detachable bobbin being set on the first PCB, a primary side winding being wound around the first structural portion of the detachable bobbin and electrically connected to the first PCB and the AC power input circuit, a second circuit module containing a second PCB, a DC power output circuit being set on the second PCB, a second structural portion of the detachable bobbin being set on the second PCB, a secondary side winding being wound around the second structural portion of the detachable bobbin and electrically connected to the second PCB and the DC power output circuit, wherein the primary side winding and the secondary side winding are assembled to form a transformer, the AC power input circuit and the DC power output circuit are structurally connected through the first structural portion and the second structural portion of the detachable bobbin while being electrically connected through the first PCB and the second PCB.

In accordance with one aspect of the disclosure, the first structural portion of the detachable bobbin includes a first winding space and a first plurality of electrical connection terminals, the primary winding is wound around the first winding space and electrically connected to the first printed circuit board through the first plurality of electrical connection terminals.

In accordance with one aspect of the disclosure, the first structural portion of the detachable bobbin further includes a first cover for covering the primary winding, having a first latch and a first slot respectively set on opposite side of the first cover.

In accordance with one aspect of the disclosure, the second structural portion of the detachable bobbin includes a second winding space and a second plurality of electrical connection terminals, the secondary winding is wound around the second winding space and electrically connected to the second printed circuit board through the secondary plurality of electrical connection terminals.

In accordance with one aspect of the disclosure, the second structural portion of the detachable bobbin further includes a second cover for covering the secondary winding, having a second latch and a second slot respectively set on opposite side of the second cover each located at corresponding position that can form latch-slot pair with the first latch and the first slot set on the first cover.

In accordance with one aspect of the disclosure, the first latch, the first slot and the second latch, the second slot are used to lock the primary winding and the secondary winding through their corresponding locking positions.

In accordance with one aspect of the disclosure, the first circuit module further comprises a power factor adjustment circuit electrically connected to the AC power input circuit, a half-bridge switching circuit electrically connected to the power factor adjustment circuit, an LLC resonant circuit electrically connected to the half-bridge switching circuit and the primary winding, and an LLC controller electrically connected to the half-bridge switching circuit and the DC power output circuit for monitoring output voltage of the DC power output circuit so as to control the switching frequency of the half-bridge switching circuit.

In accordance with one aspect of the disclosure, the DC output circuit further comprises a synchronous filter stage electrically connected to the secondary winding and a feedback stage electrically connected to the output of the synchronous filter stage.

In accordance with one aspect of the disclosure, the feedback stage includes a feedback circuit electrically connected to the output of the synchronous stage and a photo-coupler electrically connected to the feedback circuit.

In accordance with one aspect of the disclosure, the first circuit module and the second circuit module is electrically connected through an electric coupler and the electric coupler includes receptacle-pin pairs.

### BRIEF DESCRIPTION OF THE DRAWINGS

The components, characteristics and advantages of the present invention may be understood by the detailed descriptions of the preferred embodiments outlined in the specification and the drawings attached:

FIG. 1 illustrates a circuit block diagram of the AC/DC power supply according to the present invention.

FIG. 2 illustrates a separable bobbin structure used to construct a detachable transformer of the AC/DC power supply according to the present invention.

FIG. 3 illustrates a schematic assembling procedure of the AC/DC power supply according an embodiment of the present invention.

FIG. 4 illustrates another schematic assembling procedure of the AC/DC power supply according an embodiment of the present invention.

FIGS. 5-6 illustrate the transformer assembly of the AC/DC power supply according an embodiment of the present invention.

FIGS. 7-9 illustrate devices that used for electrical signal connection of the AC/DC power supply according to an embodiment of the present invention.

FIGS. 10-13 illustrate the assembling steps of the AC/DC power supply according to an embodiment of the present invention.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

In order to provide a simple and effective power supply that can be combined/disassembled, the present invention splits a conventional AC/DC power supply into an AC power input module and a DC voltage output module. For delivering different DC voltage outputs, this can be done by simply replacing the DC voltage output module of the power supply. A combined AC/DC power supply proposed in the present invention, the output DC voltage module can be replaced, and the AC power input module can be retained. Thus, an adequate DC voltage output can be chosen, development and design time for new power supply can be reduced and resource waste for developing power supply can also be minimized.

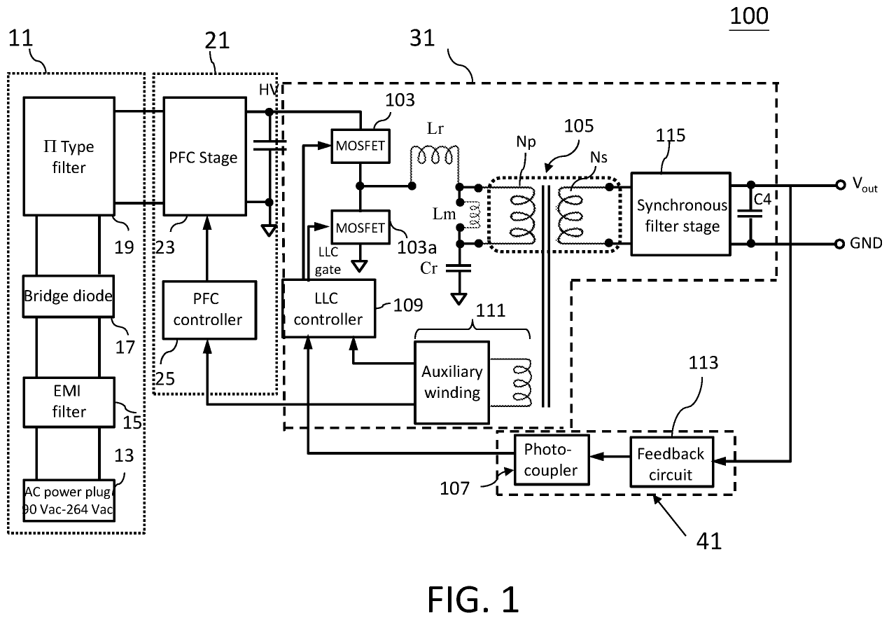

A circuit block diagram 100 of the AC/DC power supply has illustrated in FIG. 1. The left dotted-line frame is a power input stage 11, which includes an alternating current (AC) power supply plug 13 to provide AC power of 90-240 Vac, an electromagnetic interface (EMI) filter 15, a bridge diode 17, and a Π type filter 19 for rectifying and filtering the AC voltage into a DC voltage, then feeds the DC voltage into the input of a power factor adjustment circuit indicated as the middle dotted-line frame 21. The power factor adjustment circuit 21 including a power factor correction (PFC) stage 23 and a power factor correction (PFC) controller 25. The dotted-line frame on the right is a power stage 31, which includes a resonant inductor Lr, a resonant capacitor Cr and a magnetizing inductance Lm to form an LLC resonant circuit, and two metal-oxide-semiconductor field effect transistors, 103 and 103a, to form a half-bridge circuit. An LLC controller 109 provides control of gates of the two MOSFETs 103 and 103a to make their individual duty cycle a fixed 50% signal, d utilized the parasitic diodes and parasitic capacitors of the individual MOSFET to achieve zero voltage switching. The LLC resonant circuit is connected to a transformer 105 which is composed of a primary side winding Np and a secondary side winding Ns. A synchronous filter stage 115 and the output of the secondary side winding Ns are electrically connected to form a filter circuit, and a capacitor C4 is connected in parallel with load as a low-pass filter. A lower dashed-line frame is a feedback stage 41 including a feedback circuit 113 and a photo-coupler 107, where the feedback circuit 113 monitors the output voltage value Vₒᵤₜ and transmits it back to the LLC controller 109 via the photo-coupler 107 for feedback control, i.e. to adjust frequency of the two MOSFETs 103 and 103a of the primary side Np.

The resonant inductor Lr, the resonant capacitor Cr and the magnetizing inductor Lm form the LLC resonant circuit. The LLC resonant circuit (converter) has two resonant frequencies, fr1 and fr2:
a. the resonant frequency fr1 related to the resonant inductor Lr and the resonant capacitor Cr,

$$fr 1 = \frac{1}{2 π \sqrt{Lr * Cr}}$$

b. the resonant frequency fr2 related to the resonant inductor Lr, magnetizing inductor Lm and the resonant capacitor Cr,

$$fr 2 = \frac{1}{2 π \sqrt{( Lr + Lm ) * Cr}}$$

therefore, the switching frequency fs has a range fr1≤fs≤fr2. The DC characteristics of the LLC resonant circuit can be divided into zero voltage switching and zero current switching, which is more suitable for zero voltage switching in the case of MOSFETS.

Since the LLC circuit requires the resonant inductor Lr. After considering the efficiency, space and cost of the overall circuitry, a double-slot transformer is selected on the main transformer, which is mainly a wall between the primary side coil winding Np and the secondary side winding Ns. By coupling the Np and Ns to generate a leakage inductance, that is, the resonant inductance Lr, the magnetizing inductance Lm and the resonant inductance Lr can be simultaneously obtained in the double-slot transformer.

Theoretical coil ratio formula of the LLC resonant circuit can be expressed as:

$$\frac{Np}{Ns} = \frac{Vin}{2 * Vout} ⇒ Ns = \frac{2 * Vout * Np}{Vin}$$

When the input voltage Vᵢₙ is a fixed value of 390V, the output voltage Vₒᵤₜ is 12V, and the number of primary side winding Np is 32.5 Ts, the number of secondary side winding Ns can be calculated to be 2 Ts. When the output voltage Vₒᵤₜ is 18V and the number of primary side winding Np is 32.5 Ts, the number of the secondary side winding Ns is 3 Ts.

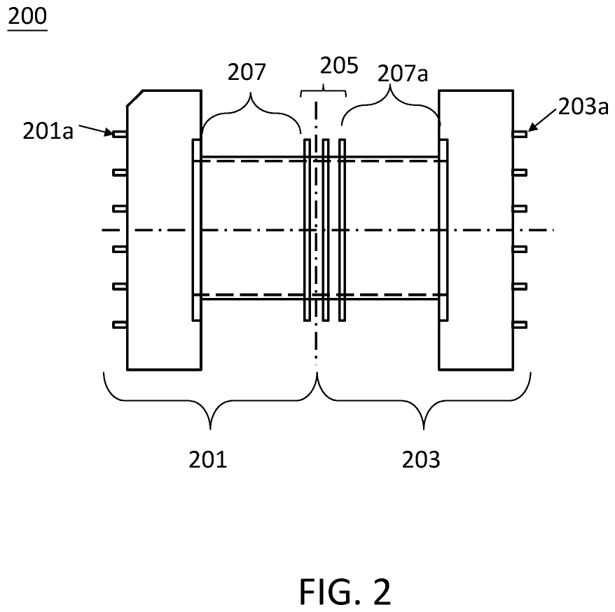

It can be seen that when the secondary side winding Ns is a multiple of 1 Ts/6V, the primary side winding Np is fixed at 32.5 Ts, therefore the concept of a separable structure can be achieved by using a split-slot transformer, as illustrated in FIG. 2.

Referring to the above LLC circuit principle, as shown in FIG. 1, the connection between the primary and the secondary sides of the integrated circuit is mainly between a transformer (including Np and Ns) 105 and a feedback stage 41. The feedback stage 41 includes the photo-coupler 107 and the feedback circuit 113. In the case where the primary side circuit is unchanged, separating the primary side winding Np and secondary side winding Ns, the original single power supply becomes a detachable power supply. The following instructions will explain how to convert the power supply into two parts that are detachable:

First the transformer is designed as separable and part of the transformer can be detached from the main connecting circuit. The structure of the bobbin 200, which is illustrated in FIG. 2, can be divide into two separated parts from the middle portion, including a left portion and a right portion. The left portion 201 is a first structural portion having a first plurality of electrical connection pins 201a, a first winding space 207 of the slotted bobbin 201, and a retaining wall structure 205. The right portion 203 is a second structural portion having a second plurality of electrical connection pins 203a and a second winding space 207a. The first structural portion 201 and the second structural portion 203 are separable.

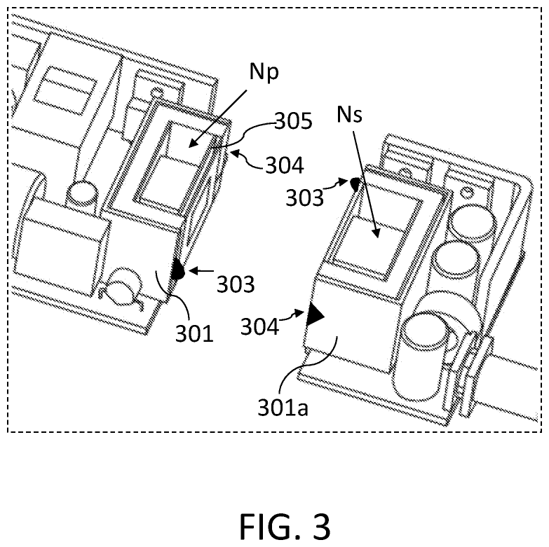

Referring to FIG. 3, a leakage inductance can be generated after assembling the separated primary side winding Np and the secondary side winding Ns and determined by the designed width of the retaining wall 305. In addition, a plurality of auxiliary positioning points 303, 304 are added to a cover of the transformer core, i.e. a first outer cover 301 and a second outer cover 301a for assisting the transformer assembly. In one of the preferred embodiment, the auxiliary positioning positions (303, 304) can be latch-slot pairs to lock the primary side winding Np and the secondary side winding Ns.

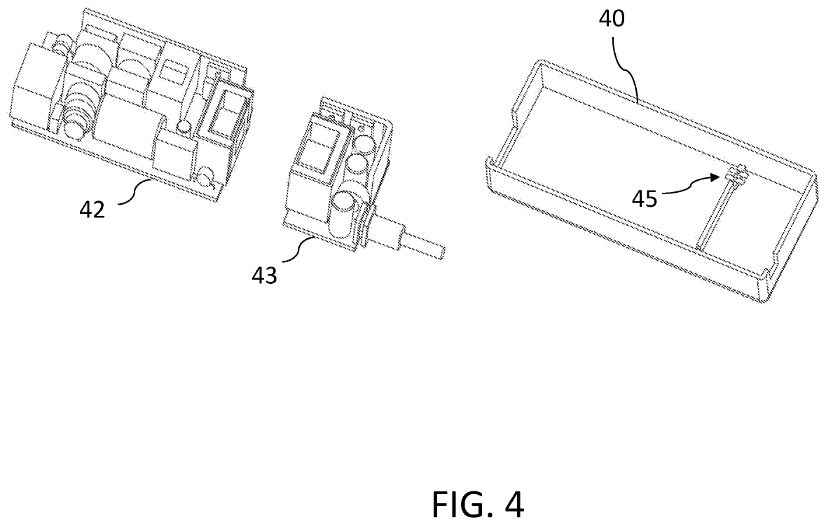

As shown in FIG. 4, the printed circuit board (PCB) is divided into two PCB modules 42 and 43 on the primary and secondary sides for respectively loading electronic components of the powers supply. The electronic components that are installed on the secondary side PCB module 43 (please refer to the circuit of FIG. 1) includes the secondary side coil winding Ns, the synchronous filter stage 115, the photo-coupler 107 and the feedback circuit 113. The two PCB modules 41 and 43 on the primary side and the secondary side are respectively connected by a structural component 45 disposed inside the power supply housing 40, and can meet the purpose that for achieving various output voltage specifications requirement by only replacing the secondary side PCB module 43 with different specification.

Since the power supply becomes detachable and can be separated into two parts. For the feedback and protection connections, please refer to FIG. 1, the power converter except transformer 105, there exists the following signals required to be supplied to the primary side:

I. the secondary side output feedback signal supplied to the primary side power management integrated circuit (IC), that is, the LLC controller 109, which can adjust switching frequency of the primary side MOSFETs 103 and 103a based on current load condition, such as heavy load, light load, very light load and no load, via the feedback circuit 113 and photo-coupler 107.

II. over voltage and over current protection (OVP/OCP) signals. Because all part of the primary side need to keep unchanged, the over voltage and over current protection are designed in the secondary side. The OVP/OCP signal in the secondary side can be matched with the corresponding protection point setting according to the output voltage. This OVP/OCP signal must be provided into the primary side power management IC (LLC controller 109) to check the current power supply operation status. If the power is in an abnormal condition, the LLC controller 109 must enter protection mode.

III. auxiliary side winding 111 voltage signal. The primary side power management IC (LLC controller 109) must have stable DC voltage supply for keeping primary side power management IC (LLC controller 109) work properly. Because the input terminal of the primary side is an AC power with input voltage ranging from 90-264 Vac, therefore the needed DC voltage of the primary side power management IC (LLC controller 109) is provided through sensing the fixed output DC voltage of the secondary side via the auxiliary side winging 111.

IV. filtering signals. Safety capacitors are typically used for anti-interfering circuits only, such as the filtering action in the synchronous filtering stage 115 shown in FIG. 1. They are used in the power supply filter to filtering out the common mode and differential mode interference. Generally, 1-2 Y capacitors are connected between the first and second (primary and secondary) sides.

The electronic components installed on the primary side PCB module 42 includes all the electronic components shown in the circuit of FIG. 1 except the electronic components that installed on the secondary side PCB module 43 and mentioned I-IV in previous paragraphs above.

For the power supply assembly, it can be explained by the following three parts, namely, the split transformer assembly, the feedback protection signal and the safety capacitor connection assembly, and the printed circuit board of the assembled parts (PCBA) on the primary side and the secondary side assembly.

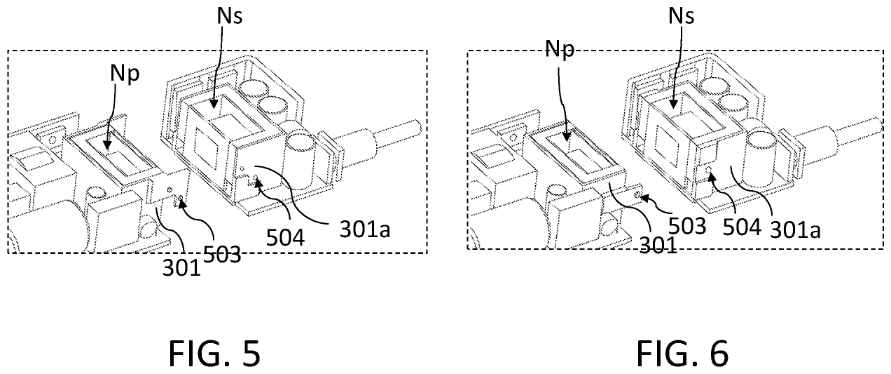

FIGS. 5-6 are schematic views showing the assembly of the split type transformer according the present invention. The primary side cover 301 has a concave positioning point 503, and the secondary side outer cover 301a has a convex positioning point 504, the combination of the two together with latch-slot structure enables the transformer to be accurately combined.

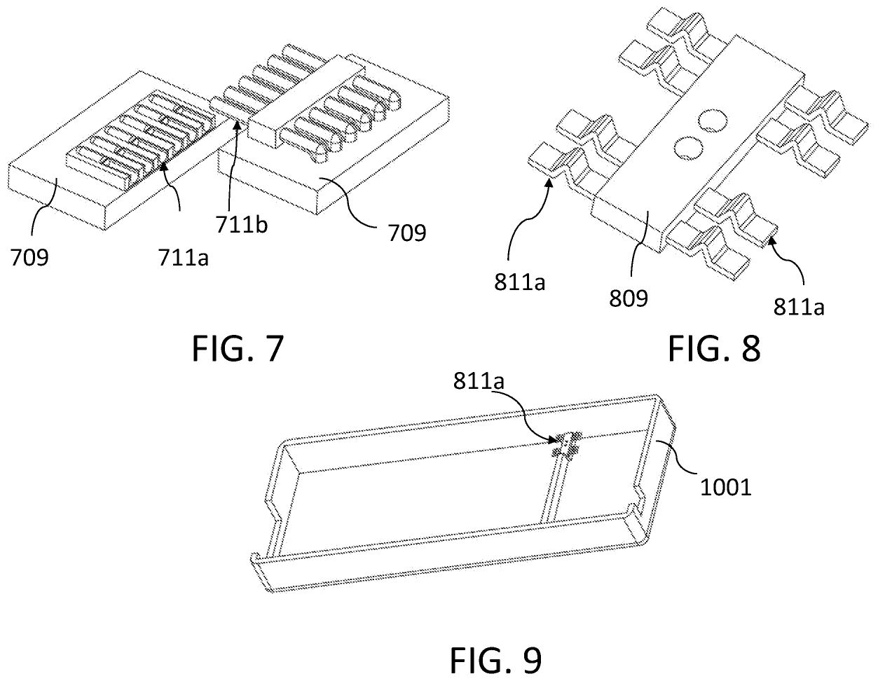

As mentioned in point III above, there must be a plurality of low-voltage and low-current signal connections between the primary and secondary sides, which can be electrically connected through the pin receptacles 711a and pins 711b as shown in FIG. 7 or through the contact of the elastic metal pieces 811a as shown in FIG. 8-9. These electrical connection members such as, elastic metal pieces 811a, pin receptacles 711a and pins 711b are set on bases 709 and 809 accordingly for fixing them on the printed circuit board PCB or the bottom case 1001.

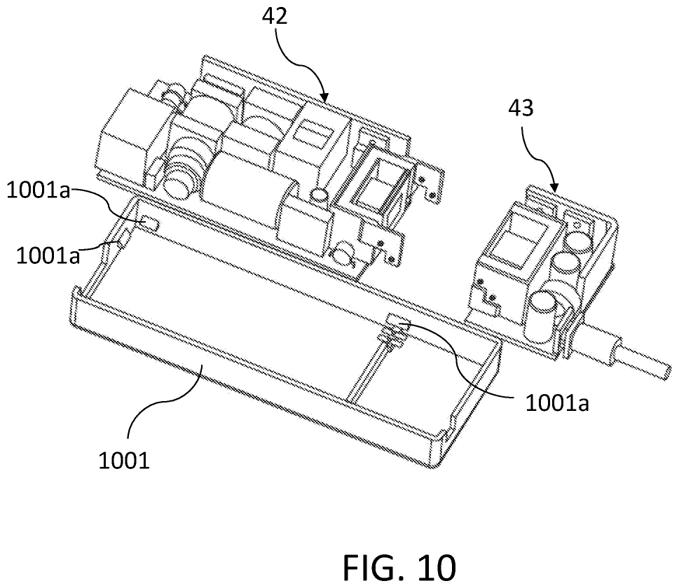

For the assembly and fixing of the PCBA (41, 43) of the primary side and the secondary side, as shown in FIG. 10, the above-mentioned split type transformer assembly is first completed (i.e., through the latch-groove, concave-bump pair positioning points combination), feedback protection signal and safety capacitor connection assembly (that is, through the receptacle-pin pairs or the elastic metal pieces for the signal connection, and respectively fixed to the printed circuit board PCB or the bottom casing through their corresponding base), the bottom case 1001 with ribs 1001a provides primary side and secondary side PCB module (41, 43) aligned into bottom case 1001.

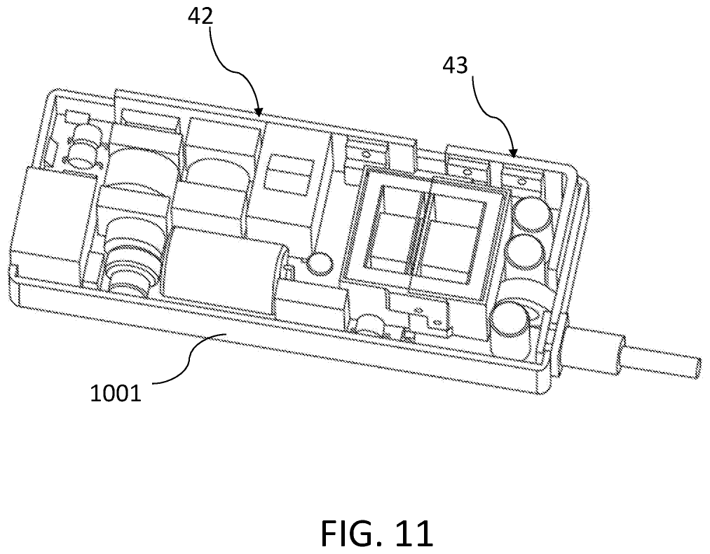

FIG. 11 illustrates the two PCBAs (41, 43) after assembling with the bottom case 1001.

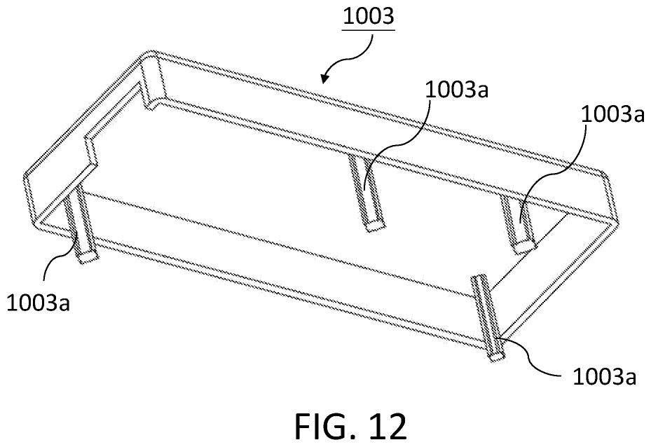

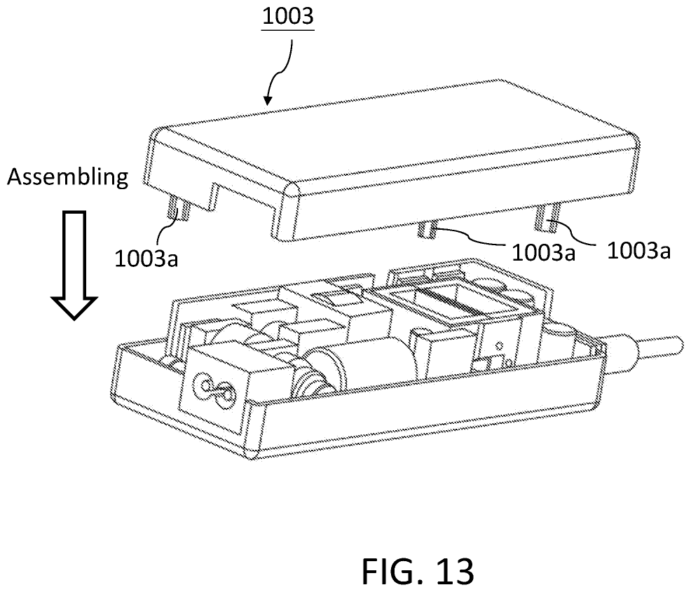

Next, as shown in FIG. 12, a top case 1003 with ribs 1003a at positions in the primary side corresponding to the secondary side is provided for subsequent assembly. Subsequently, as shown in FIG. 13, the top case 1003 having ribs 1003a being pressed from above to the PCBAs (41, 43) that have been assembled on bottom case to form a power supply. FIGS. 10-13 illustrate the entire assembly process.

According to the contents described above, the present invention has the following advantages:

(1). By replacing the output DC voltage module and retaining the AC voltage output module, the desired DC voltage output can be selected.

(2). Power supply development and design time can be reduced and resource waste can be minimized.

Thus, an adequate DC voltage output can be chosen, development and design time for new power supply can be reduced and resource waste for developing power supply can also be minimized.

As will be understood by persons skilled in the art, the foregoing preferred embodiment of the present invention illustrates the present invention rather than limiting the present invention. Having described the invention in connection with a preferred embodiment, modifications will be suggested to those skilled in the art. Thus, the invention is not to be limited to this embodiment, but rather the invention is intended to cover various modifications and similar arrangements included within the spirit and scope of the appended claims, the scope of which should be accorded the broadest interpretation, thereby encompassing all such modifications and similar structures. While the preferred embodiment of the invention has been illustrated and described, it will be appreciated that various changes can be made without departing from the spirit and scope of the invention.

What is claimed is:

1. A combined type AC/DC power supply, comprising:
a first circuit module including:
a first printed circuit board;
an AC power input circuit being set on the first printed circuit board;
a first structural portion of a detachable bobbin being set on the first printed circuit board;
a primary side winding being wound around the first structural portion of the detachable bobbin and electrically connected to the first printed circuit board and the AC power input circuit;
a second circuit module including:
a second printed circuit board;
a DC power output circuit being set on the second printed circuit board;
a second structural portion of the detachable bobbin being set on the second printed circuit board;
a secondary side winding being wound around the second structural portion of the detachable bobbin and electrically connected to the second printed circuit board and the DC power output circuit;
wherein the primary side winding and the secondary side winding are assembled to form a transformer; and
wherein the AC power input circuit and the DC power output circuit are structurally connected through the first structural portion and the second portion of the detachable bobbin while being electrically connected through the first printed circuit board and the second printed circuit board.

2. The combined type AC/DC power supply of claim 1, wherein the first structural portion of the detachable bobbin includes a first winding space and a first plurality of electrical connection terminals, the primary winding is wound around the first winding space and electrically connected to the first printed circuit board through the first plurality of electrical connection terminals.

3. The combined type AC/DC power supply of claim 1, wherein the first structural portion of the detachable bobbin further includes a first cover for covering the primary winding, having a first latch and a first slot respectively set on opposite side of the first cover.

4. The combined type AC/DC power supply of claim 1, wherein the second structural portion of the detachable bobbin includes a second winding space and a second plurality of electrical connection terminals, the secondary winding is wound around the second winding space and electrically connected to the second printed circuit board through the secondary plurality of electrical connection terminals.

5. The combined type AC/DC power supply of claim 4, wherein the second structural portion of the detachable bobbin further includes a second cover for covering the secondary winding, having a second latch and a second slot respectively set on opposite side of the second cover each located at corresponding position that can form latch-slot pair with the first latch and the first slot set on the first cover.

6. The combined type AC/DC power supply of claim 3, wherein the first latch, the first slot and the second latch, the second slot are used to lock the primary winding and the secondary winding through their corresponding locking positions.

7. The combined type AC/DC power supply of claim 5, wherein the first latch, the first slot and the second latch, the second slot are used to lock the primary winding and the secondary winding through their corresponding locking positions

8. The combined type AC/DC power supply of claim 1, wherein the first circuit module further comprises:
a power factor adjustment circuit electrically connected to the AC power input circuit;
a half-bridge switching circuit electrically connected to the power factor adjustment circuit;
an LLC resonant circuit electrically connected to the half-bridge switching circuit and the primary winding; and
an LLC controller electrically connected to the half-bridge switching circuit and the DC power output circuit for monitoring output voltage of the DC power output circuit so as to control the switching frequency of the half-bridge switching circuit.

9. The combined type AC/DC power supply of claim 1, wherein the DC power output circuit further comprises:
a synchronous filter stage electrically connected to the output of the secondary winding; and
a feedback stage electrically connected to the output of the synchronous filter stage.

10. The combined type AC/DC power supply of claim 9, wherein the feedback stage includes:
a feedback circuit electrically connected to the output of the synchronous stage; and
a photo-coupler electrically connected to the feedback circuit.

11. The combined type AC/DC power supply of claim 1, wherein the first circuit module and the second circuit module is electrically connected through an electric coupler and the electric coupler includes receptacle-pin pairs.

12. A combined type AC/DC power supply, comprising:
a first circuit module including:
a first printed circuit board;
an AC power input circuit being set on the first printed circuit board;
a primary side winding being electrically connected to the first printed circuit board and the AC power input circuit;
a second circuit module including:
a second printed circuit board;
a DC power output circuit being set on the second printed circuit board;
a secondary side winding being electrically connected to the second printed circuit board and the DC power output circuit;
wherein the primary side winding and the secondary side winding are assembled to form a transformer; and
wherein the AC power input circuit and the DC power output circuit are structurally connected through the first structural portion and the second portion of the detachable bobbin while being electrically connected through the first printed circuit board and the second printed circuit board.

13. The combined type AC/DC power supply of claim 12, wherein the first circuit module further comprising:
a first structural portion of a detachable bobbin being set on the first printed circuit board, including a first winding space and a first plurality of electrical connection terminals, wherein the primary winding is wound around the first winding space and electrically connected to the first printed circuit board through the first plurality of electrical connection terminals.

14. The combined type AC/DC power supply of claim 13, wherein the first structural portion of the detachable bobbin further includes a first cover for covering the primary winding, having a first latch and a first slot respectively set on opposite side of the first cover.

15. The combined type AC/DC power supply of claim 12, wherein the second circuit module further comprising:
a second structural portion of a detachable bobbin being set on the second printed circuit board, including a second winding space and a second plurality of electrical connection terminals, wherein the secondary winding is wound around the second winding space and electrically connected to the second printed circuit board through the second plurality of electrical connection terminals.

16. The combined type AC/DC power supply of claim 15, wherein the second structural portion of the detachable bobbin includes a second winding space and a second plurality of electrical connection terminals, the secondary winding is wound around the second winding space and electrically connected to the second printed circuit board through the secondary plurality of electrical connection terminals.

17. combined type AC/DC power supply of claim 15, wherein the second structural portion of the detachable bobbin further includes a second cover for covering the secondary winding, having a second latch and a second slot respectively set on opposite side of the second cover each located at corresponding position that can form latch-slot pair with the first latch and the first slot set on the first cover.

18. The combined type AC/DC power supply of claim 14, wherein the first latch, the first slot and the second latch, the second slot are used to lock the primary winding and the secondary winding through their corresponding locking positions.

19. The combined type AC/DC power supply of claim 17, wherein the first latch, the first slot and the second latch, the second slot are used to lock the primary winding and the secondary winding through their corresponding locking positions.

20. The combined type AC/DC power supply of claim 12, wherein the first circuit module further comprises:
a power factor adjustment circuit electrically connected to the AC power input circuit;
a half-bridge switching circuit electrically connected to the power factor adjustment circuit;
an LLC resonant circuit electrically connected to the half-bridge switching circuit and the primary winding; and
an LLC controller electrically connected to the half-bridge switching circuit and the DC power output circuit for monitoring output voltage of the DC power output circuit so as to control the switching frequency of the half-bridge switching circuit.

21. The combined type AC/DC power supply of claim 12, wherein the DC power output circuit further comprises:
a synchronous filter stage electrically connected to the secondary winding; and
a feedback stage electrically connected to the output of the synchronous filter stage.

22. The combined type AC/DC power supply of claim 12, wherein the feedback stage includes:
a feedback circuit electrically connected to the output of the synchronous stage; and
a photo-coupler electrically connected to the feedback circuit.
